(19) United States
(12) Patent Application Publication
(10) Pub. No.: US 2018/0138414 A1
(43) Pub. Date: May 17, 2018

(54) ORGANIC LIGHT-EMITTING DEVICE

(71) Applicants: Cambridge Display Technology Limited, Cambridgeshire (GB); Sumitomo Chemical Company Limited, Tokyo (JP)

(72) Inventors: Michael Cass, Godmanchester (GB); Matthew Roberts, Godmanchester (GB); Natasha M.J. Conway, watford (GB)

(73) Assignees: Cambridge Display Technology Limited, Cambridgeshire (GB); Sumitomo Chemical Company Limited, Tokyo (JP)

(21) Appl. No.: 15/574,386

(22) PCT Filed: May 13, 2016
(86) PCT No.: PCT/GB2016/051383

§ 371 Date: Nov. 15, 2017

(30) Foreign Application Priority Data
May 15, 2015 (GB) 1508442.9

(51) Int. Cl. H01L 51/00; H01L 51/50; C08G 61/02; C08G 61/12

(52) U.S. Cl. CPC H01L 51/0043; H01L 51/5004; C08G 61/02; H01L 51/0039; H01L 51/56; H01L 2251/552; H01L 51/5012; H01L 51/5016; C08G 61/128

(57) ABSTRACT

An organic light-emitting device comprising an anode (101), a cathode (105) and an homogeneous organic light-emitting layer (103) between the anode and the cathode wherein: the light-emitting layer comprises a first light-emitting material mixed with an inert material; the inert material has a HOMO level (HOMO_{IM}) that is further from vacuum than a HOMO level (HOMO_{LEM}) of the first light-emitting material and a LUMO level (LUMO_{IM}) that is closer to vacuum than a LUMO level(LUMO_{LEM}) of the first light-emitting material; and the inert material comprises up to 25 weight % of the light-emitting layer.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Light-emitting materials for use in an organic light-emitting layer include polymeric and non-polymeric materials. A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton). Phosphorescent dopants are also known (that is, a light-emitting dopant in which light is emitted via decay of a triplet exciton).

US 2010/193776 discloses a light-emitting layer containing an electrically inert binder material for confining holes in the light-emitting layer. A hole-transporting host material in the light-emitting layer is graded such that its concentration increases towards the anode. An electron-transporting emissive material in the light-emitting layer is graded such that its concentration increases towards the cathode.

Mohan et al, http://arxiv.org/ftp/arxiv/papers/1107/1107.2695.pdf discloses a 1:1 mixture of Alq₃ and an inert diluent material. The inert diluent has a high ionization potential to confine holes in the light-emitting layer.

It is an object of the invention to improve efficiency of organic light-emitting devices.

### SUMMARY OF THE INVENTION

In a first aspect the invention provides an organic light-emitting device comprising an anode, a cathode and an homogeneous organic light-emitting layer between the anode and the cathode wherein: the light-emitting layer comprises a first light-emitting material mixed with an inert material; the inert material has a HOMO level that is further from vacuum than a HOMO level of the first light-emitting material and a LUMO level that is closer to vacuum than a LUMO level of the first light-emitting material; and the inert material comprises up to 25 mol % of the light-emitting layer.

In a second aspect the invention provides a formulation comprising a first light-emitting material, an inert material and at least one solvent wherein the inert material has a HOMO level that is further from vacuum than a HOMO level of the first light-emitting material and a LUMO level that is closer to vacuum than a LUMO level of the first light-emitting material, and wherein the inert material comprises up to 25 mol % of the formulation excluding the or each solvent.

In a third aspect the invention provides a method of forming an organic light-emitting device according to the first aspect comprising the step of depositing a formulation according to the second aspect onto one of the anode and cathode and evaporating the at least one solvent to form the light-emitting layer, and forming the other of the anode and cathode over the light-emitting layer.

### DESCRIPTION OF THE DRAWINGS

The invention will now be described in more detail with reference to the drawings in which:

FIG. 1 illustrates schematically an OLED according to an embodiment of the invention;

FIG. 2 illustrates schematically the HOMO and LUMO levels of an inert material and a light-emitting polymer of a composition according to an embodiment of the invention;

FIG. 3 illustrates schematically the lowest excited state energy levels of an inert material and a light-emitting polymer of a composition according to an embodiment of the invention;

FIG. 4 is a graph of efficiency vs time for a device according to an embodiment of the invention and a comparative device;

FIG. 5 is a graph of luminance vs. time for a device according to an embodiment of the invention and a comparative device;

FIG. 6 is a graph of CIE(y) vs. inert material concentration for devices of varying inert material concentration; and

FIG. 7 is a time-resolved photoluminescence plot for a device according to an embodiment of the invention and a comparative device.

### DETAILED DESCRIPTION OF THE INVENTION

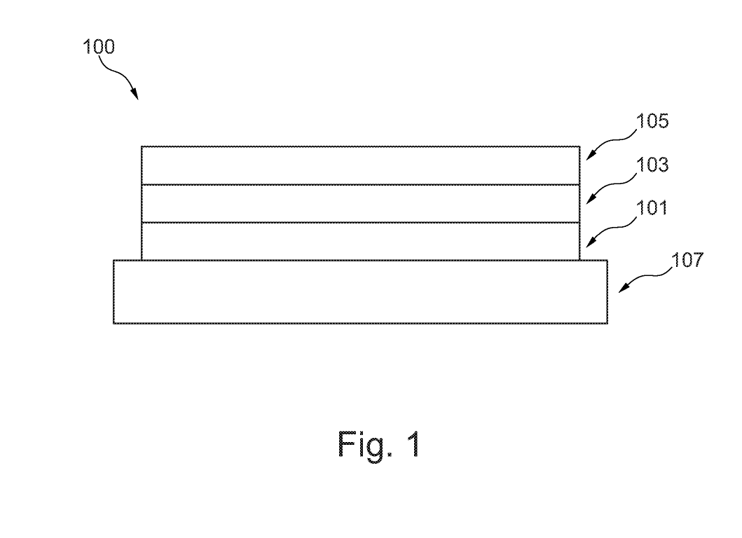

FIG. 1, which is not drawn to any scale, illustrates an OLED 100 according to an embodiment of the invention supported on a substrate 107, for example a glass or plastic substrate. The OLED 100 comprises an anode 101, a light-emitting layer 103 and a cathode 105.

Light-emitting layer 103 is a homogeneous layer comprising a mixture of a first organic light-emitting material and an inert material, preferably an inert organic material.

By “homogeneous” as used herein is meant that the components of the light-emitting layer are distributed evenly throughout the layer. Homogeneous light-emitting layer 103 may be formed by depositing the components of light-emitting layer from a solution and evaporating the solvent or solvents of the solution.

By “inert material” as used herein is meant a material having a HOMO level that is deeper (further from vacuum level) than the HOMO level of the first organic light-emitting material, and a LUMO level that is shallower (closer to vacuum) than the LUMO level of the first organic light-emitting material.

The present inventors have surprisingly found that such an arrangement can increase efficiency of an organic light-emitting device as compared to a device in which the inert material is absent, even at low concentrations of the inert material. The inert material may form 0.1-25 mol % of the components of the light-emitting layer 103, optionally 1-25 mol % or 1-15 mol %.

One or more further layers may be provided between the anode 103 and cathode 105, for example hole-transporting layers, electron transporting layers, hole blocking layers and electron blocking layers. The device may contain more than one light-emitting layer.

Preferred device structures include:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

Preferably, at least one of a hole-transporting layer and a hole injection layer is present. Preferably, both a hole injection layer and a hole-transporting layer are present.

In one embodiment substantially all light emitted during operation of the device 100 is emitted from light-emitting materials in light-emitting layer 103.

In other embodiments, two or more layers of the device may emit light during operation of the device. Optionally, one or more charge-transporting layers may comprise a light-emitting dopant such that the charge-transporting layer(s) emit light during operation of the device.

The OLED 100 may be a full colour display comprising a plurality of pixels, each pixel comprising at least red, green and blue subpixels.

The OLED 100 may be a white-emitting OLED wherein light-emitting layer 103 alone emits white light or wherein emission from light-emitting layer 103 and another emitting layer combine to produce white light. White light may be produced from a combination of red, green and blue light-emitting materials.

White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

Preferably, light-emitting layer 103 comprises a blue light-emitting material.

The photoluminescence spectrum of a non-polymeric material may be measured by casting 5 wt % of the material in a PMMA film onto a quartz substrate to achieve transmittance values of 0.3-0.4 and measuring in a nitrogen environment using apparatus C9920-02 supplied by Hamamatsu. The photoluminescence spectrum of a polymeric material may be measured in the same way using a neat film of the polymeric material.

Optionally, the absorption and emission spectra of the light-emitting material overlap.

The light-emitting material of light-emitting layer 103, and any further light-emitting materials present in light-emitting layer 103 or in another layer, may each independently be selected from fluorescent materials and phosphorescent materials.

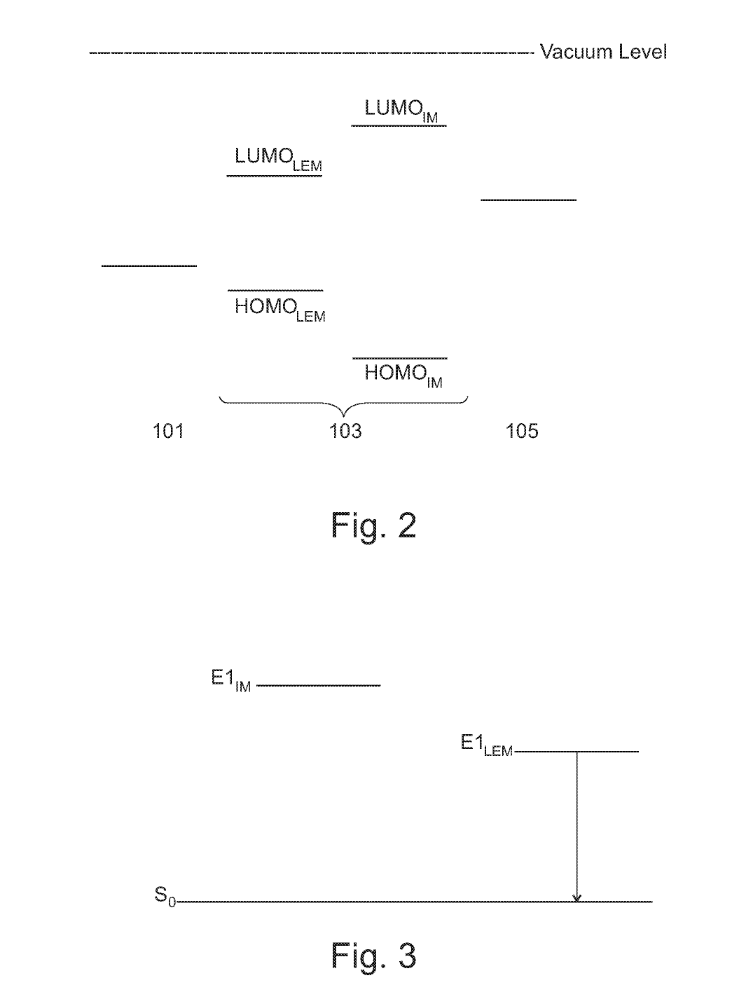

With reference to FIG. 2, the inert material has a HOMO level HOMO_{IM} that is deeper (further from vacuum level) than the HOMO level HOMO_{LEM} of the light-emitting material, and a LUMO level LUMO_{IM} that is shallower (closer to vacuum) than the LUMO level LUMO_{LEM} of the light-emitting material. Preferably, HOMO_{IM} is at least 0.1 eV, preferably at least 0.2 or 0.3 eV, deeper than HOMO_{LEM}. Preferably, LUMO_{IM} is at least 0.1 eV, preferably at least 0.2 or 0.3 eV, shallower than LUMO_{LEM}.

In operation, holes are injected from anode 101 having a work function WF_{A} and electrons are injected from cathode 105 having a work function WF_{C}. Holes and/or electrons may be injected directly into the HOMO and LUMO respectively of the light-emitting material or one or more charge transporting or charge injecting layers may be provided between the anode 101 and light-emitting layer 103 and/or between the cathode 105 and light-emitting layer 103. The HOMO and LUMO levels of the inert material are such that the inert material provides no, or negligible, charge transport or emission.

With reference to FIG. 3, in operation the light-emitting material emits light by radiative decay of an exciton from a lowest excited state energy level E1_{LEM} of the light-emitting material to ground state S₀. The inert material, having a lowest excited state energy level E1_{IM} that is higher than the lowest excited state energy level E1_{LEM} of the light-emitting material, is non-emissive. Preferably, E1_{IM} is at least 0.2, 0.3 or 0.4 eV higher than the lowest excited state energy level E1_{LEM}.

If the light-emitting material is a fluorescent material then the inert material has a lowest singlet excited state energy level (S₁) that is higher than that of the fluorescent material. If the light-emitting material is a phosphorescent material then the inert material has a lowest triplet excited state energy level (T₁) that is higher than that of the phosphorescent material.

Light-emitting layer 103 may consist essentially of the first light-emitting material and the inert material or it may contain one or more further materials. The one or more further materials may be selected from hole-transporting materials, electron-transporting materials and further light-emitting materials. If light-emitting layer 103 contains both a fluorescent and a phosphorescent material then the S₁ and T₁ levels of the inert material are higher than the S₁ and T₁ levels of the fluorescent and phosphorescent materials respectively.

The inert material may be a non-polymeric organic semiconductor or polymeric semiconductor. Preferably, the inert material is a semiconducting polymer. The inert semiconducting polymer may be a non-conjugated polymer having conjugated side groups. Preferably, the inert semiconducting polymer is a conjugated polymer, more preferably a conjugated polymer comprising one or more arylene repeat units. Preferably, the repeat units of the inert semiconducting polymer consist of arylene repeat units.

Exemplary arylene repeat units are phenylene, fluorene, indenofluorene and phenanthrene repeat units, each of which may be unsubstituted or substituted with one or more substituents. Preferably, the repeat units of the inert semiconducting polymer comprise or consist of fluorene and/or phenylene repeat units.

An arylene repeat unit of the inert polymer may be substituted with one or more substituents, optionally one or more C₁₋₄₀ hydrocarbyl substituents, optionally a substituent selected from unsubstituted phenyl; phenyl substituted with one or more C₁₋₁₀ alkyl groups; and C₁₋₂₀ alkyl. A substituent of an arylene repeat unit may be provided adjacent to one or each linking position of the arylene repeat unit.

Phenylene repeat units may have formula (VI):

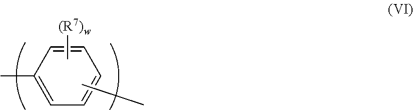

wherein w in each occurrence is independently 0, 1, 2, 3 or 4, optionally 1 or 2; and R⁷ independently in each occurrence is a substituent.

Where present, each R⁷ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups; and
a linear or branched chain of aryl or heteroaryl groups, each of which groups may independently be substituted, for example a group of formula —(Ar⁷)ᵣ wherein each Ar⁷ is independently an aryl or heteroaryl group and r is at least 2, preferably a branched or linear chain of phenyl groups each of which may be unsubstituted or substituted with one or more C₁₋₂₀ alkyl groups.

In the case where R⁷ comprises an aryl or heteroaryl group, or a linear or branched chain of aryl or heteroaryl groups, the or each aryl or heteroaryl group may be substituted with one or more substituents R⁸ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F;
NR⁹₂, OR⁹, SR⁹, SiR⁹₃ and
fluorine, nitro and cyano;

wherein each R⁹ is independently selected from the group consisting of alkyl, preferably C₁₋₂₀ alkyl; and aryl or heteroaryl, preferably phenyl, optionally substituted with one or more C₁₋₂₀ alkyl groups.

Substituted N, where present, may be —NR⁶— wherein R⁶ is a substituent and is optionally a C₁₋₄₀ hydrocarbyl group, optionally a C₁₋₂₀ alkyl group.

Preferably, each R⁷, where present, is independently selected from a group of formula (I), (IIa) or (IIb), and C₁₋₄₀ hydrocarbyl. Preferred C₁₋₄₀ hydrocarbyl groups are C₁₋₂₀ alkyl; unsubstituted phenyl; phenyl substituted with one or more C₁₋₂₀ alkyl groups; and a linear or branched chain of phenyl groups, wherein each phenyl may be unsubstituted or substituted with one or more substituents.

Exemplary repeat units of formula (VI) include the following:

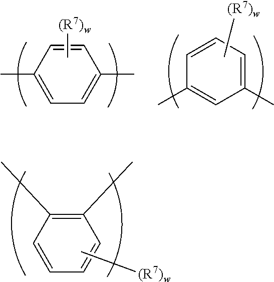

A particularly preferred repeat unit of formula (VI) has formula (VIa):

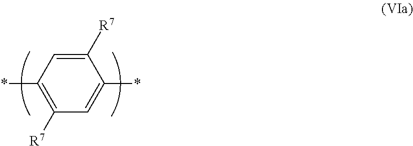

Substituents R⁷ of formula (VIa) are adjacent to linking positions of the repeat unit, which may cause steric hindrance between the repeat unit of formula (VIa) and adjacent repeat units, resulting in the repeat unit of formula (VIa) twisting out of plane relative to one or both adjacent repeat units and increasing the band gap of the polymer as compared to a polymer in which substituents R⁷ are not present.

Fluorene repeat units may have formula (VII):

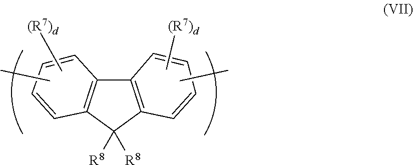

wherein R⁸ in each occurrence is the same or different and is a substituent wherein the two groups R⁸ may be linked to form a ring; R⁷ is a substituent as described above; and d is 0, 1, 2 or 3.

Each R⁸ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups; and
a linear or branched chain of aryl or heteroaryl groups, each of which groups may independently be substituted, for example a group of formula —(Ar⁷)ᵣ wherein each Ar⁷ is independently an aryl or heteroaryl group and r is at least 2, optionally 2 or 3, preferably a branched or linear chain of phenyl groups each of which may be unsubstituted or substituted with one or more C₁₋₂₀ alkyl groups.

Preferably, each R⁸ is independently a a C₁₋₄₀ hydrocarbyl group. Preferred C₁₋₄₀ hydrocarbyl groups are C₁₋₂₀ alkyl; unsubstituted phenyl; phenyl substituted with one or more C₁₋₂₀ alkyl groups; and a linear or branched chain of phenyl groups, wherein each phenyl may be unsubstituted or substituted with one or more C₁₋₂₀ alkyl groups.

Substituted N, where present, may be —NR⁶— wherein R⁶ is as described above.

The aromatic carbon atoms of the fluorene repeat unit may be unsubstituted, or may be substituted with one or more substituents R⁷ as described with reference to Formula (VI).

Exemplary substituents R⁷ are alkyl, for example C₁₋₂₀ alkyl, wherein one or more non-adjacent C atoms may be replaced with O, S, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

The extent of conjugation of repeat units of formula (VII) to aryl or heteroaryl groups of adjacent repeat units in the polymer backbone may be controlled by (a) linking the repeat unit through the 3- and/or 6-positions to limit the extent of conjugation across the repeat unit, and/or (b) substituting the repeat unit with one or more substituents R⁷ in or more positions adjacent to the linking positions in order to create a twist with the adjacent repeat unit or units, for example a 2,7-linked fluorene carrying a C₁₋₂₀ alkyl substituent in one or both of the 3- and 6-positions.

The repeat unit of formula (VII) may be a 2,7-linked repeat unit of formula (VIIa):

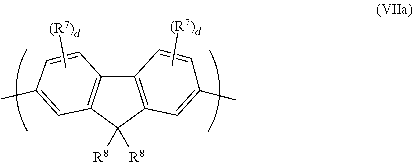

A relatively high degree of conjugation across the repeat unit of formula (VIIa) may be provided in the case where each d=0, or where any substituent R⁷ is not present at a position adjacent to the linking 2- or 7-positions of formula (VIIa).

A relatively low degree of conjugation across the repeat unit of formula (VIIa) may be provided in the case where at least one d is at least 1, and where at least one substituent R⁷ is present at a position adjacent to the linking 2- or 7-positions of formula (VIIa). Optionally, each d is 1 and the 3- and/or 6-position of the repeat unit of formula (VIIa) is substituted with a substituent R⁷ to provide a relatively low degree of conjugation across the repeat unit.

The repeat unit of formula (VII) may be a 3,6-linked repeat unit of formula (VIIb)

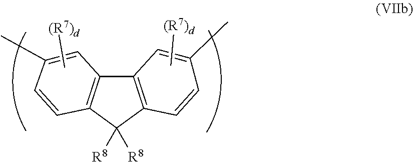

The extent of conjugation across a repeat unit of formula (VIIb) may be relatively low as compared to a corresponding repeat unit of formula (VIIa).

Another exemplary arylene repeat unit has formula (VIII):

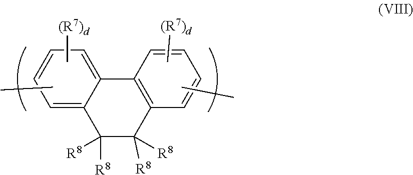

wherein R⁷, R⁸ and d are as described with reference to formulae (VI) and (VII) above. Any of the R⁸ groups may be linked to any other of the R⁸ groups to form a ring. The ring so formed may be unsubstituted or may be substituted with one or more substituents, optionally one or more C₁₋₂₀ alkyl groups.

Repeat units of formula (VIII) may have formula (VIIIa) or (VIIIb):

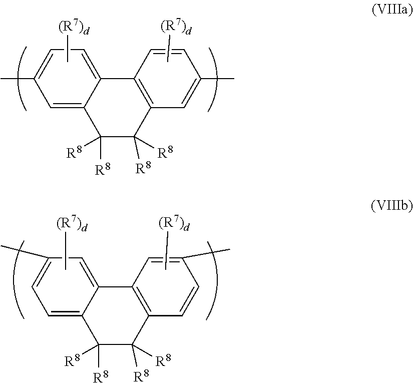

Light-Emitting Materials

Light-emitting materials may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12: 1737-1750, 2000, the contents of which are incorporated herein by reference.

A conjugated light-emitting polymer may comprise one or more amine repeat units of formula (IX):

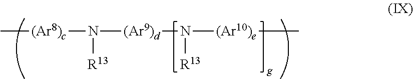

wherein Ar⁸, Ar⁹ and A¹⁰ in each occurrence are independently selected from substituted or unsubstituted aryl or heteroaryl, g is 0, 1 or 2, preferably 0 or 1, R¹³ independently in each occurrence is H or a substituent, preferably a substituent, and c, d and e are each independently 1, 2 or 3.

A light-emitting polymer comprising repeat units of formula (IX) may further comprise one or more arylene repeat units. Arylene repeat units may be as described with reference to the inert polymer, any may be selected from repeat units of formulae (VI), (VII) and (VIII) as described above.

R¹³, which may be the same or different in each occurrence when g is 1 or 2, is preferably selected from the group consisting of alkyl, for example C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar¹⁰ and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ aryl, more preferably phenyl, that may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R¹³ is preferably Ar¹¹ or a branched or linear chain of Ar¹¹ groups. Ar¹¹ in each occurrence is preferably phenyl that may be unsubstituted or substituted with one or more substituents.

Exemplary groups R¹³ include the following, each of which may be unsubstituted or substituted with one or more substituents, and wherein * represents a point of attachment to N:

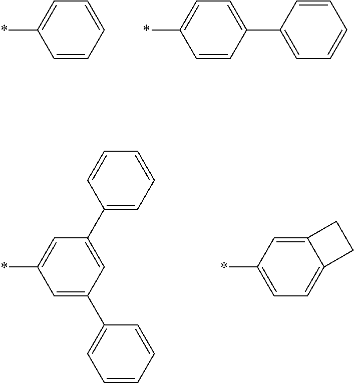

c, d and e are preferably each 1.

Ar⁸, Ar⁹, and, if present, Ar¹⁰ and Ar¹¹ are each independently unsubstituted or substituted with one or more, optionally 1, 2, 3 or 4, substituents. Exemplary substituents may be selected from substituted or unsubstituted alkyl, optionally C₁₋₂₀ alkyl, wherein one or more non-adjacent C atoms may be replaced with optionally substituted aryl or heteroaryl (preferably phenyl), O, S, C═O or —COO— and one or more H atoms may be replaced with F.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (IX) include unsubstituted or substituted units of formulae (IX-1), (IX-2) and (IX-3):

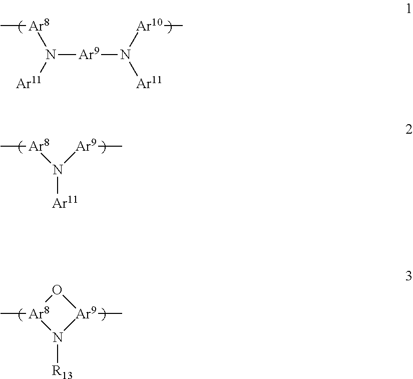

Polymers as described herein including, without limitation, inert polymers and light-emitting polymers, may have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷.

Polymers as described herein including, without limitation, inert polymers and light-emitting polymers, are preferably amorphous.

The first light-emitting material may be a fluorescent or phosphorescent dopant provided in light-emitting layer 103 with a semiconducting host material. Exemplary phosphorescent dopants are row 2 or row 3 transition metal complexes, for example complexes of ruthenium, rhodium, palladium, rhenium, osmium, iridium, platinum or gold. Iridium is particularly preferred. If present, a semiconducting host material has a HOMO-LUMO bandgap that is narrower than that of the inert material. Preferably, the HOMO of the inert material is at least 0.1 eV, preferably at least 0.2 or 0.3 eV, deeper than the HOMO of the host material. Preferably, the LUMO of the inert material is at least 0.1 eV, preferably at least 0.2 or 0.3 eV, shallower than the LUMO of the host material.

Charge Transporting and Charge Blocking Layers

A hole transporting layer may be provided between the anode and the light-emitting layer or layers. An electron transporting layer may be provided between the cathode and the light-emitting layer or layers.

An electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A hole transporting layer preferably has a HOMO level of less than or equal to 5.5 eV, more preferably around 4.8-5.5 eV as measured by square wave voltammetry. The HOMO level of the hole transport layer may be selected so as to be within 0.2 eV, optionally within 0.1 eV, of an adjacent layer (such as a light-emitting layer) in order to provide a small barrier to hole transport between these layers. A hole-transporting polymer may comprise or consist of a polymer comprising a repeat unit of formula (IX) as described above.

An electron transporting layer located between the light-emitting layers and cathode preferably has a LUMO level of around 2.5-3.5 eV as measured by square wave voltammetry. For example, a layer of a silicon monoxide or silicon dioxide or other thin dielectric layer having thickness in the range of 0.2-2 nm may be provided between the light-emitting layer nearest the cathode and the cathode.

An electron transporting layer may contain a polymer comprising a chain of optionally substituted arylene repeat units, such as a chain of fluorene repeat units.

Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

Cathode

The cathode 105 is selected from materials that have a work function allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low work function material and a high work function material such as calcium and aluminium, for example as disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 0.5-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; sodium fluoride; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

Organic optoelectronic devices tend to be sensitive to moisture and oxygen.

Accordingly, the substrate 107 preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

Formulation Processing

A formulation suitable for forming a light-emitting layer may be formed from the inert material, light-emitting material and a solvent. A “solvent” as described herein may be a single solvent material or a mixture of two or more solvent materials. The formulation is preferably a solution.

Solvents suitable for dissolving the compound of formula (I) include, without limitation, benzenes substituted with one or more C₁₋₁₀ alkyl or C₁₋₁₀ alkoxy groups, for example toluene, xylenes and methylanisoles, and mixtures thereof.

Particularly preferred solution deposition techniques including printing and coating techniques such spin-coating and inkjet printing.

Spin-coating is particularly suitable for devices wherein patterning of the light-emitting layer is unnecessary—for example for lighting applications or simple monochrome segmented displays.

Inkjet printing is particularly suitable for high information content displays, in particular full colour displays. A device may be inkjet printed by providing a patterned layer over the anode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing, screen printing and slot-die coating.

### EXAMPLES

Inert Polymer 1

Inert Polymer 1 was prepared by polymerising the following monomers by Suzuki polymerisation as described in WO 00/53656:

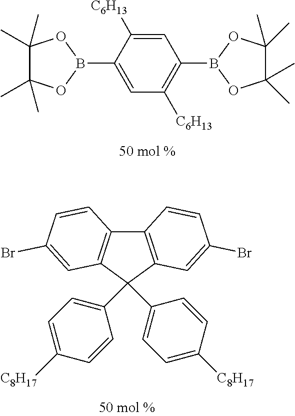

Light-Emitting Polymer 1

A fluorescent blue light emitting polymer was prepared by Suzuki polymerisation as described in WO 00/53656 of fluorene monomers of formula (VIIa); monomers of formula (VIIa) and amine monomers of formulae (IX-1) and (IX-3).

Light-Emitting Polymer 2

A fluorescent blue light emitting polymer was prepared by Suzuki polymerisation as described in WO 00/53656 of fluorene monomers of formula (VIIa) and amine monomers of formula (IX-1).

### Formulation Example 1

Light Emitting Polymer 1 (90 mol %) and Inert Polymer 1 (10 mol %) were dissolved in mixed xylenes to form an solution having a concentration of 1-2 w/w %.

The molar percentage of a given polymer as stated herein is based on the average molecular weight of all repeat units of the polymer weighted according to the molar ratio for each repeat unit in the polymer.

Measurements

HOMO and LUMO levels as described herein are as measured by square wave voltammetry.

The working electrode potential may be ramped linearly versus time. When square wave voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinum counter electrode (donor or acceptor of electrons) and a reference glass electrode no leak Ag/AgCl. Ferrocene is added in the cell at the end of the experiment for calculation purposes.

Measurement of the difference of potential between Ag/AgCl/ferrocene and sample/ferrocene.

Method and settings:

3 mm diameter glassy carbon working electrode

Ag/AgCl/no leak reference electrode

Pt wire auxiliary electrode

0.1 M tetrabutylammonium hexafluorophosphate in acetonitrile

LUMO=4.8−ferrocene (peak to peak maximum average)+onset

Sample: 1 drop of 5 mg/mL in toluene spun at 3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline. HOMO and LUMO values may be measured at ambient temperature.

S₁ and T₁ values of a material may be measured by photoluminescence spectroscopy of an 80 nm thick film of the material onto a quartz substrate in a nitrogen environment using apparatus C9920-02 supplied by Hamamatsu.

S₁ values of a material as described herein may be obtained from its room temperature fluorescence spectrum.

T₁ values of a material as described herein may be measured from the energy onset of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

S₁ and T₁ values are taken from the spectral position of the half maximum of the short-wavelength side of the emission peak.

Results are provided in Table 1.

| | Inert Polymer 1 | Light-Emitting Polymer 1 |
|---|---|---|
| HOMO (eV) | 6.0 | 5.2 |
| LUMO (eV) | 1.9 | 2.2 |
| S₁ (eV) | 3.35 | 2.75 |
| T₁ (eV) | 2.48 | 2.15 |

### Device Example 1

A blue fluorescent organic light-emitting device having the following structure was prepared:

ITO (45 nm)/HIL (35 nm)/HTL (ca. 20 nm)/LE (65 nm)/Cathode,

wherein ITO is an indium-tin oxide anode; HIL is a hole-injecting layer; HTL is a hole-transporting layer; LE is a light-emitting layer; and the cathode comprises a layer of sodium fluoride in contact with the light-emitting layer and a layer of silver and a layer of aluminium.

To form the device, a substrate carrying ITO was cleaned using UV/Ozone. The hole injection layer was formed by spin-coating an aqueous formulation of a hole-injection material available from Nissan Chemical Industries and heating the resultant layer. The hole transporting layer was formed by spin-coating Hole-Transporting Polymer 1 and crosslinking the polymer by heating. The light-emitting layer was formed by spin-coating composition of Light-Emitting Polymer 1:Inert Polymer 1 (90:10 wt/wt). The cathode was formed by evaporation of a first layer of sodium fluoride to a thickness of about 2 nm, a second layer of aluminium to a thickness of about 100 nm and a third layer of silver to a thickness of about 100 nm.

Comparative Device 1

For the purpose of comparison a device was prepared as described in Device Example 1 except that Inert Polymer 1 was not included in the light-emitting layer, and the hole-transporting layer was provided at a thickness of 22 nm to achieve the same colour as Device Example 1.

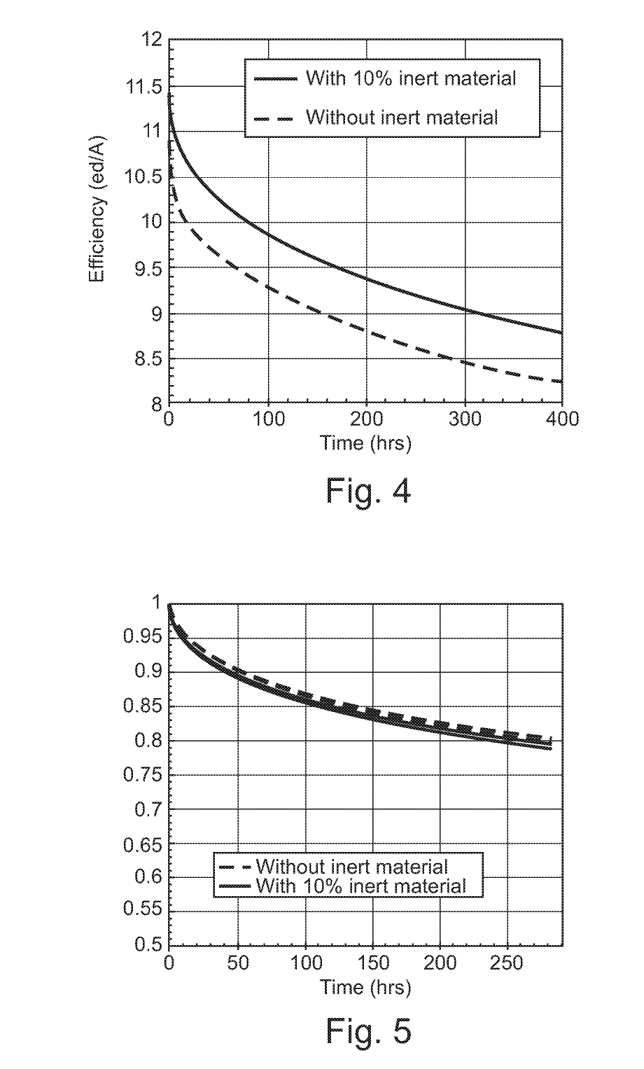

With reference to FIG. 4, the efficiency of Device Example 1 is higher than that of Comparative Device 1.

With reference to FIG. 5, the brightnesses of Device Example 1 and Comparative Device 1 decay at a similar rate.

### Device Example 2

Devices were prepared as for Device Example 1 except that Light-Emitting Polymer 2 was used in place of Light-Emitting Polymer 1 and the molar ratio of inert material was varied from 0 mol % up to 90 mol %. Without wishing to be bound by any theory, it is believed that the inert material allows more light to be outcoupled, and may reduce self-absorption of light by the light-emitting material as compared to a device in which the inert material is absent.

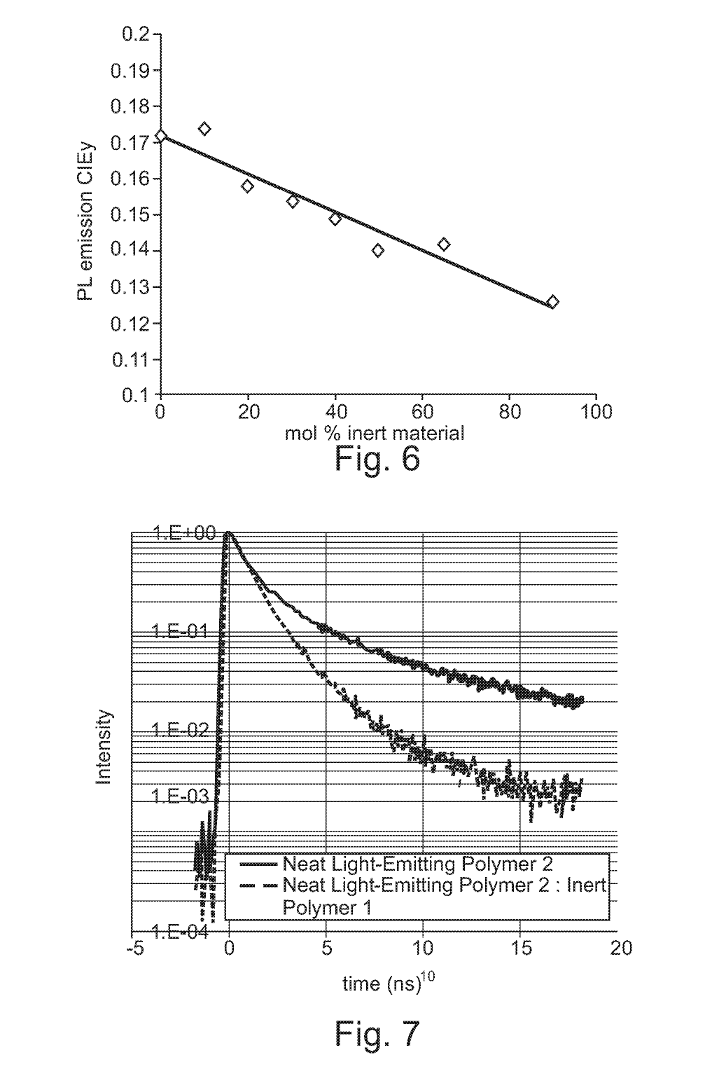

FIG. 7 is a plot of time-resolved photoluminescence of a neat film of Light-Emitting Polymer 2 and a composition of Light-emitting Polymer 2:Inert Polymer 1 (90:10). Excitons of the composition containing Inert Polymer 1 undergo radiative decay faster than excitons generated in the neat film of Light-Emitting Polymer 2.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic light-emitting device comprising an anode, a cathode and an homogeneous organic light-emitting layer between the anode and the cathode wherein: the light-emitting layer comprises a first light-emitting material mixed with an inert material; the inert material has a HOMO level that is further from vacuum than a HOMO level of the first light-emitting material and a LUMO level that is closer to vacuum than a LUMO level of the first light-emitting material; and the inert material comprises up to 25 mol % of the light-emitting layer.

2. The organic light-emitting device according to claim 1, wherein the first light-emitting material is a fluorescent material and the lowest singlet excited state energy level of the fluorescent material is lower than the lowest singlet excited state energy level of the inert material.

3. The organic light-emitting device according to claim 1, wherein the first light-emitting material is a phosphorescent material and the lowest triplet excited state energy level of the phosphorescent material is lower than the lowest triplet excited state energy level of the inert material

4. The organic light-emitting device according to claim 1, wherein the first light-emitting material is a blue light-emitting material.

5. The organic light-emitting device according to claim 1, wherein the first light-emitting material is a polymer.

6. The organic light-emitting device according to claim 5, wherein the first light-emitting material comprises a repeat unit of formula (IX): 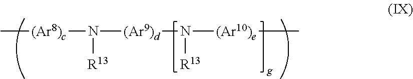
wherein Ar⁸, Ar⁹ and Ar¹⁰ in each occurrence are independently selected from substituted or unsubstituted aryl or heteroaryl, g is 0, 1 or 2, R¹³ independently in each occurrence is H or a substituent, and c, d and e are each independently 1, 2 or 3.

7. The organic light-emitting device according to claim 1, wherein the inert material is a polymer.

8. The organic light-emitting device according to claim 7, wherein the inert material comprises one or more arylene repeat units that may be unsubstituted or substituted with one or more substituents.

9. The organic light-emitting device according to claim 8, wherein the repeat units of the inert material consists of arylene repeat units that may be unsubstituted or substituted with one or more substituents.

10. The organic light-emitting device according to claim 1, wherein the inert material comprises 1-15 mol % of the light-emitting layer.

11. A formulation comprising a first light-emitting material, an inert material and at least one solvent wherein the inert material has a HOMO level that is further from vacuum than a HOMO level of the first light-emitting material and a LUMO level that is closer to vacuum than a LUMO level of the first light-emitting material, and wherein the inert material comprises up to 25 mol % of the formulation excluding the at least one solvent.

12. A method of forming the organic light-emitting device according to claim 1, comprising the step of depositing a formulation comprising a first light-emitting material, an inert material and at least one solvent wherein the inert material has a HOMO level that is further from vacuum than a HOMO level of the first light-emitting material and a LUMO level that is closer to vacuum than a LUMO level of the first light-emitting material, and wherein the inert material comprises up to 25 mol % of the formulation excluding the at least one solvent onto one of the anode and cathode and evaporating the at least one solvent to form the light-emitting layer, and forming the other of the anode and cathode over the light-emitting layer.
